(19) United States
(12) Patent Application Publication
(10) Pub. No.: US 2009/0212811 A1
(43) Pub. Date: Aug. 27, 2009

(54) Semiconductor device and method for testing the same

(75) Inventor: Masao Iruka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/379,286

(22) Filed: Feb. 18, 2009

(30) Foreign Application Priority Data
Feb. 25, 2008 (JP) 43131/2008

(51) Int. Cl. G01R 31/26

(52) U.S. Cl. 324/765

(57) ABSTRACT

A method for testing a semiconductor device having plural transmitting (TX) circuits and plural receiving (RX) circuits at a low cost and in a short time. The semiconductor device includes two or more pairs of transmitting and receiving circuits. Each of the transmitting circuits converts parallel data to serial data and transmits the converted serial data to external while each of the receiving circuits receives serial data from external and converts the received serial data to parallel data. Furthermore, the semiconductor device includes a device that enables two or more selected pairs of transmitting and receiving circuits to be connected serially and alternately. The semiconductor device can be configured so that the serially connected transmitting or receiving circuit in the first stage inputs a test signal to be compared with a signal output from the serially connected receiving or transmitting circuit in the last stage.

### FIELD OF THE INVENTION

The present invention relates to a semiconductor device and a method for testing the same, more particularly to a semiconductor device having a transmitting circuit that converts parallel data to serial data and sends the converted serial data to external and a receiving circuit that receives serial data from external and converts the received serial data to parallel data, and a method for testing the semiconductor device.

### BACKGROUND OF THE INVENTION

Serial communications that can realize fast data transfer rates have been the main stream for the conventional communication systems. And in recent years, integrated circuits (IC) employed for those communication systems that exchange serial data with each another have come to use a circuit that converts serial data inputted from external to low speed parallel data so as to be processed in various ways therein respectively, then converts the processed parallel data to high speed serial data to be output to external.

Testers used generally for inspecting those ICs before their delivery cannot cover the frequencies of the high speed serial data as described above. And such testers that can input/output such high speed serial data are expensive. So, if such a tester is used for IC inspections, the price is naturally added to the IC cost, thereby the price of the IC comes to rise.

This is why it is a general way now to built a self-test circuit (BIST circuit: Built-In Self-Test) in each object IC so as to carry out such IC tests therein.

FIG. 6 is a concept diagram for a loop-back test carried out by using a self-test circuit as described above. A test signal generation circuit 93 built in the object IC outputs parallel data to a transmitting (TX) circuit 91 that converts the parallel data to serial data. The IC itself is driven with an actual operation frequency. The serial data converted by the transmitting (TX) circuit 91 is looped back through a loop-back path 95 provided inside or outside the subject IC so as to be inputted to a receiving (RX) circuit 92 that converts serial data to parallel data. The receiving (RX) circuit 92 converts serial data to parallel data and outputs the converted parallel data to a test signal comparison circuit 94. The test signal conversion circuit 94 compares the inputted parallel data with test data to check whether or not the test data is sent to the object correctly. Consequently, the object IC having the transmitting (TX) circuit 91 and the receiving (RX) circuit 92 comes to be tested with the actual operation frequency.

LSI Corporation, “White Paper 6G Data Over Legacy Backplane”, URL (http://www/lsi.com/files/docs/marketing docs/asic/6%20GB%20Ethernet%20White%20Paper%20Final.pdf) (non-patent document 1) discloses a method for testing an IC having plural transmitting (TX) circuits and plural receiving (RX) circuits. As shown in FIG. 2 on page 3 of the non-patent document 1, each transmitting (TX) circuit includes a test signal generation circuit PRBS (Pseudo Random Binary Sequence) that generates parallel data, which is then converted to serial data through a transmitting (TX) circuit. This serial data is looped back through a BIST path as shown in FIG. 4 on page 6 of the document 1 and inputted to a test signal comparison circuit BEST Comp (Binary Error Rate Test Comparator) to be subjected to serial-parallel conversion, then subjected to data comparison, thereby the signal test is carried out. In case of the configuration shown in FIG. 5 on page 6 of the document 1, however, there is only one test signal comparison circuit BEST Com. Consequently, the plural transmitting (TX) circuits are tested sequentially. On the other hand, in case of the receiving (RX) circuit test, serial data generated by the test signal generation circuit PRBS Gen disposed in the center is inputted to each RX circuit so as to be converted to parallel data, which is then compared with reference data in the PRBS/BEST Comparator (see FIG. 3 on page 4 of the document 1) built in each receiving circuit (RX circuit) to carry out the test.

TI Corporation, “TLK4015 data sheet: Quad 0.6 to 1.5 Gbps Transceiver (Rev. B)”, URL (http://focus.tij.co.jp/jp/lit/ds/symlink/tlk4015.pdf) (non-patent document 2) (page 4) discloses a configuration of a semiconductor device having a transmitting (TX) circuit having a test signal generation circuit PRBS Generator and a receiving (RX) circuit having a test signal generation circuit PRBS Verification. On and after page 9 of the document 2 is described how the test signal comparison circuit PRBS Verification confirms test results. The PRBS Verification circuit converts parallel data generated by the test signal generation circuit PRBS Generator to serial data through a transmitting (TX) circuit and loops back the serial data so as to be inputted to the object receiving (RX) circuit and converted to parallel data and inputted to the PRBS Verification circuit.

### SUMMARY OF THE INVENTION

The above-described loop-back test is carried out for a pair of a transmitting (TX) circuit and a receiving (RX) circuit. When testing plural pairs of transmitting (TX) circuits and receiving (RX) circuits, therefore, the test must be repeated at least as many as the same number of those pairs. Thus it takes a long time and this has been a problem.

For example, in case of the technique disclosed in the non-patent document 1, when inspecting four transmitting (TX) circuits, it is required to input the serial data output from the test signal generation circuit PRBS built in each of those transmitting (TX) circuits to the test signal comparison circuit BERT Comp four times sequentially so as to be compared with the test data respectively.

On the other hand, as disclosed in the non-patent document 2, if a testing circuit is built in each of the transmitting (TX) circuits and the receiving (RX) circuits, the test can be carried out for plural pairs of transmitting (TX) circuits and receiving (RX) circuits in parallel to shorten the test time. In this case, however, the circuit scale comes to increase. This has been another problem.

Under such circumstances, it is an object of the present invention to provide a semiconductor device in one aspect. The semiconductor device includes two or more transmitting circuits and two or more receiving circuits. Each of the transmitting circuits converts parallel data to serial data and sends the converted serial data to external and each of the receiving circuits receives serial data from external and converts the received serial data to parallel data. The semiconductor device further includes a device that enables two or more selected pairs of transmitting and receiving circuits to be connected serially and alternately. And the serially connected transmitting or receiving circuit in the first stage inputs a test signal and carries out a test by comparing the test signal with a signal output from the serially connected receiving or transmitting circuit in the last stage.

It is another object of the present invention to provide a method for testing a semiconductor device that includes two or more transmitting circuits and two or more receiving circuits in another aspect. Each of the transmitting circuits converts parallel data to serial data and sends the converted serial data to external and each of the receiving circuits receives serial data from external and converts the received serial data to parallel data. And the method enables two or more selected pairs of transmitting and receiving circuits to be connected serially and alternately and enables the serially connected transmitting or receiving circuit in the first stage to input a test signal and carries out a test by comparing the test signal with a signal output from the serially connected receiving or transmitting circuit in the last stage.

According to the present invention, therefore, it is possible to carry out a test for a semiconductor device that includes plural transmitting (TX) circuits and plural receiving (RX) circuits at a low cost and in a short time. This is because the semiconductor device is configured so as to carry out a test for the plural pairs of transmitting (TX) and receiving (RX) circuits simultaneously without increasing the circuit scale.

### BRIEF DESCRIPTION OF THE DRAWINGS

FIG. 1 is a block diagram of a configuration of a semiconductor device in a first embodiment of the present invention;

FIG. 2 is a block diagram of a variation of the configuration of the semiconductor device in the first embodiment of the present invention;

FIG. 3 is a block diagram of a configuration of a semiconductor device in a second embodiment of the present invention;

FIG. 4 is a block diagram of a variation of the configuration of the semiconductor device in the second embodiment of the present invention;

FIG. 5 is a block diagram of a variation of a configuration of a semiconductor device in a third embodiment of the present invention; and

FIG. 6 is a diagram for describing a loop-back test.

### DETAILED DESCRIPTION OF THE PREFERRED EMBODIMENTS

Hereunder, there will be described in detail the preferred embodiments of the present invention with reference to the accompanying drawings.

### First Embodiment

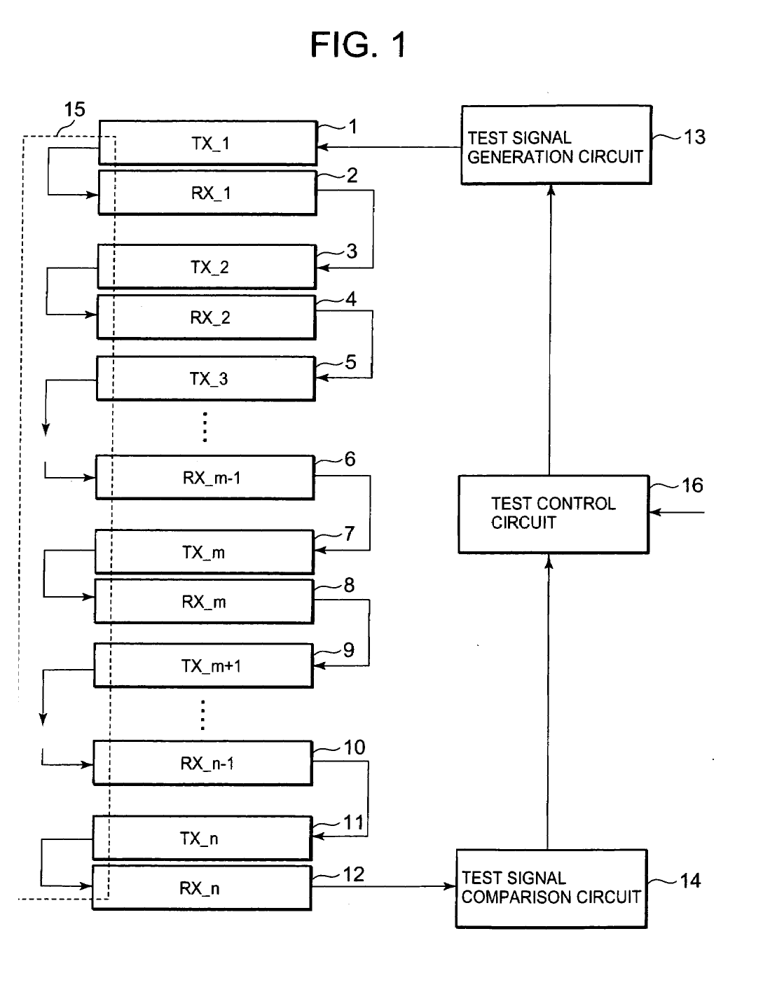

FIG. 1 is a block diagram of a configuration of a semiconductor device in this first embodiment of the present invention.

As shown in FIG. 1, the semiconductor device has plural receiving (RX) circuits and plural receiving (RX) circuits.

Each of the receiving (RX) circuits converts fast serial data received from external to parallel data and each of the transmitting (TX) circuits converts internally generated parallel data to fast serial data.

In the example shown in FIG. 1, it is premised that the semiconductor device has n pairs of transmitting (TX) circuits (TX_1 to TX_n) and receiving (RX) circuits (RX_1 to RX_n) (n>1). The n pairs of transmitting (TX) and receiving (RX) circuits are connected serially and alternately through a loop-back path 15 and an internal path so that each pair of test object transmitting (TX) and receiving (RX) circuits converts data output from the circuit in the preceding stage and outputs data that can be converted by the circuit in the subsequent stage.

A test control circuit 16 switches among the test object circuits (not shown) to enable the pairs of transmitting (TX) and receiving (RX) circuits to be connected serially and alternately as shown in FIG. 1. The test control circuit 16 also outputs control signals to a test signal generation circuit 13.

The test signal generation circuit 13 is then connected to the (first) transmitting circuit (TX_1) 1 in the first stage to output test parallel data. The transmitting circuit (TX_1) 1 is included among the pairs of transmitting (TX) and receiving (RX) circuits connected serially and alternately as described above.

The first transmitting circuit (TX_1) 1 converts the parallel data inputted from the test signal generation circuit 13 to serial data. The serial data output from the first transmitting circuit (TX_l) 1 is inputted to the first receiving circuit (RX_1) 2 through the loop-back path 15 set outside or inside the subject semiconductor device.

The first receiving circuit (RX_1) 2 converts the serial data inputted from the first transmitting circuit (TX_1) 1 to parallel data. The parallel data output from the first receiving circuit (RX-1) 2 is inputted to the second transmitting circuit (TX_2) 3 through the internal path.

The second transmitting circuit (TX_2) 3 converts the parallel data inputted from the first receiving circuit (RX_1) 2 to serial data. Similarly, the serial data output from the second transmitting circuit (TX_2) 3 is inputted to the second receiving circuit (RX_2) 4 through the loop-back path 15.

The second receiving circuit (RX_2) 4 converts the serial data inputted from the second transmitting circuit (TX_2) 3 to parallel data. The parallel data output from the second receiving circuit (RX_2) 4 is inputted to the third transmitting circuit (TX_3) 5 through the internal path.

Similarly, them-th transmitting circuit (TX_m) 7 converts the parallel data inputted from the m−1st receiving circuit (RX_m−1) 6 to serial data. Similarly, the serial data output from the m-th transmitting circuit (TX_m) 7 is inputted to the m-th receiving circuit (RX_m) 8 through the loop-back path 15.

The m-th receiving circuit (RX_m) 8 converts the serial data inputted from the m-th transmitting circuit (TX_m) 7 to parallel data. The parallel data output from the m-th receiving circuit (RX_m) 8 is inputted to the m+1st transmitting circuit (TX_m+1) 9 through the internal path.

Furthermore, the n-th transmitting circuit (TX_n) 11 converts the parallel data inputted from the n−1st receiving circuit (RX_n−1) 10 to serial data. The serial data output from the n-th transmitting circuit (TX_n) 11 is inputted to the n-th receiving circuit (RX_n) 12 through the loop-back path 15.

The n-th receiving circuit (RX_n) 12 in the last stage converts the serial data inputted from the n-th transmitting circuit (TX_n) 11 to parallel data, which is then inputted to the test signal comparison circuit 14 through the internal path.

The test signal comparison circuit 14 compares the parallel data output from the n-th receiving circuit (RX_n) 12 in the last stage with the parallel data generated by the test signal generation circuit 13 and outputs the test result.

As described above, this first embodiment can carry out the tests for the n pairs of transmitting (TX) and receiving (RX) circuits simultaneously. And in the first embodiment, it is premised that m is m≧2 and m<n, but the “n” may be any value that is over 2. For example, if n=2 is assumed, the parallel data output from the second receiving circuit (RX_2) 4 comes to be inputted to the test signal comparison circuit 14.

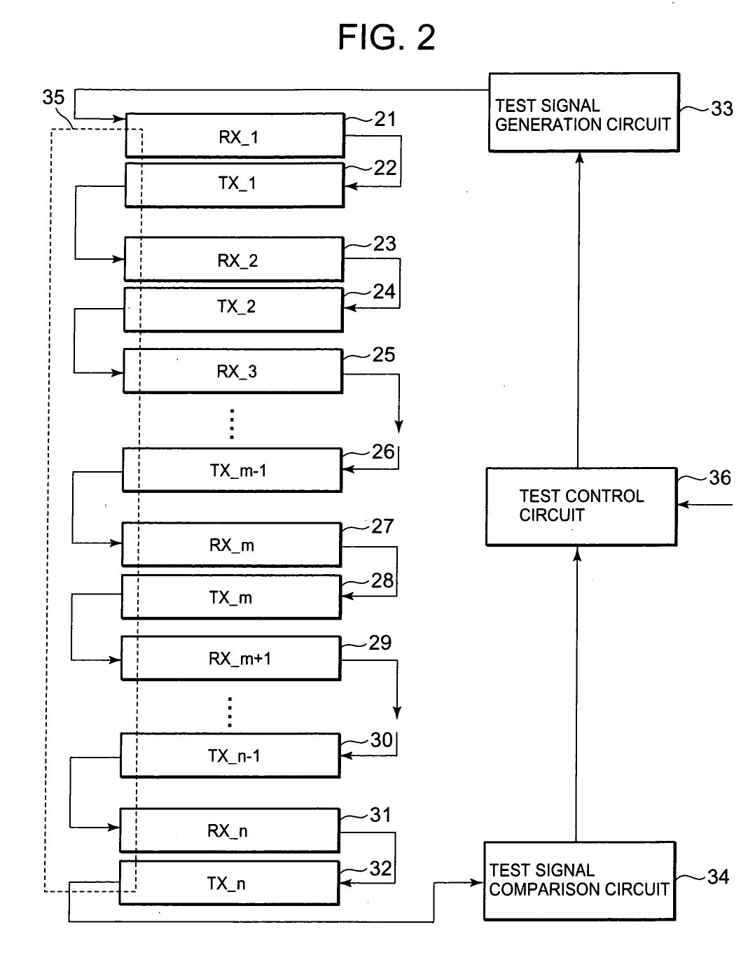

This completes the description for the first embodiment of the present invention. However, as shown in FIG. 2, the test signal generation circuit 33 may be connected to the receiving (RX) circuit in the first stage and the test signal comparison circuit 34 may be connected to the transmitting (TX) circuit in the last stage. In this case, the test signal generation circuit 33 generates serial data according to the instruction from the test control circuit 36 and the serial data is inputted to the receiving (RX_1) circuit 21 in the first stage. Then, the test signal comparison circuit 34 compares the serial data output from the (n-th) transmitting circuit (TX_n) 32 with the serial data generated in the test signal generation circuit 33 and outputs the test result.

### Second Embodiment

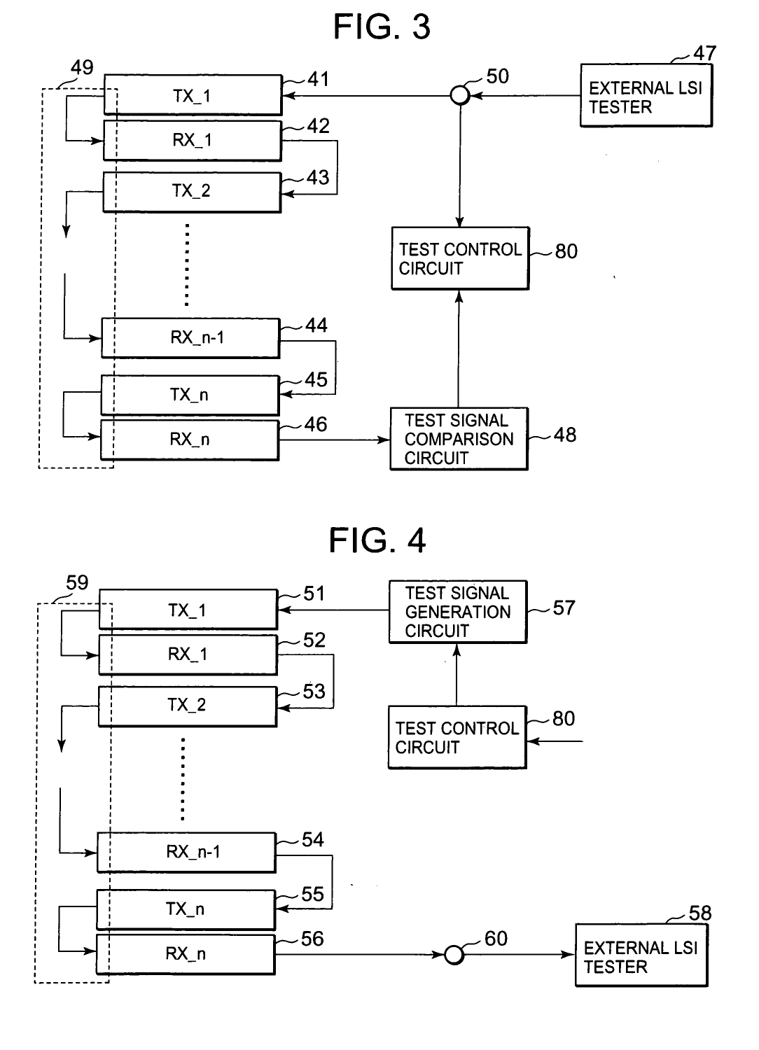

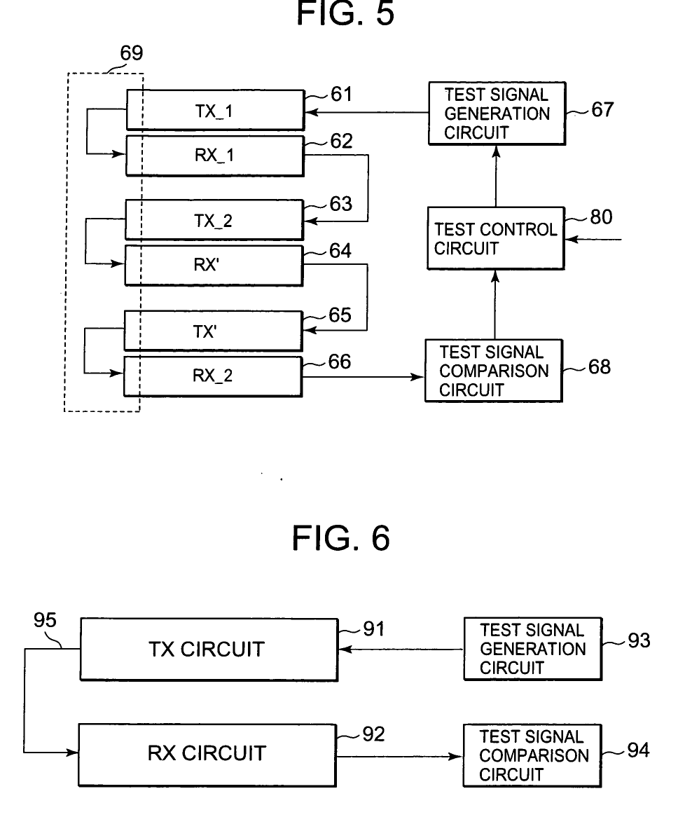

Next, there will be described in detail the second embodiment of the present invention with the accompanying drawings. FIG. 3 is a block diagram of a configuration of a semiconductor device in this second embodiment of the present invention. In this second embodiment, the semiconductor device does not include a built-in test signal generation circuit. The semiconductor device inputs the test signal from an external LSI tester through an external pin 50.

Even in this second embodiment, when a test is started, the test control circuit 80 enables the pairs of transmitting (TX) and receiving (RX) circuits to be connected serially and alternately. The serial data output from the transmitting circuit (TX_1) 41 in the first stage is inputted to the first receiving circuit (RX_1) 42 through a loop-back path 49 set outside or inside the subject semiconductor device.

The first receiving circuit (RX_1) 42 converts the serial data inputted from the transmitting circuit (TX_1) 41 in the first stage to parallel data and outputs the converted parallel data to the second transmitting circuit (TX_2) 43 through the internal path.

Similarly, the n-th transmitting circuit (TX_n) 45 converts the parallel data inputted from the n−1st receiving circuit (RX_n−1) 44 to serial data and outputs the converted serial data to the n-th receiving circuit (RX_n). 46 through the loop-back path 49.

And the n-th receiving circuit (RX_n) 46 converts the serial data inputted from the n-th transmitting circuit (TX_n) 45 to parallel data and outputs the converted parallel data to the test signal comparison circuit 48 through the internal path.

The test signal comparison circuit 48 then compares the parallel data output from the n-th receiving circuit (RX_n) 46 with the parallel data inputted from the external LSI tester 47 and outputs the test result.

As described above, this second embodiment can omit the test signal generation circuit that is required in the first embodiment, thereby reducing the circuit in scale more than the first embodiment.

This completes the description for the second embodiment of the present invention. However, as shown in FIG. 4, the test signal generation circuit 57 may also be built in the semiconductor device and the parallel data output from the receiving circuit (RX_n) 57 in the last stage can be compared in the external LSI tester 58. In this case, the test can be carried out with a frequency that cannot be covered by the external LSI tester. Furthermore, the semiconductor device can also be configured so that the external LSI tester carries out both test signal generation and data comparison and the receiving (RX) circuit in the first stage inputs serial data and the serial data is compared with the serial data output from the transmitting (TX) circuit in the last stage.

### Third Embodiment

Next, there will be described in detail the third embodiment of the present invention with reference to the accompanying drawings. FIG. 5 is a block diagram of a configuration of a semiconductor device in this third embodiment of the present invention. The semiconductor device in this third embodiment is configured so that a test receiving (RX′) circuit 64 or transmitting (TX′) circuit 65 are provided so as to be paired with a transmitting (TX) or receiving (RX) circuit.

This third embodiment can thus generate each pair of a transmitting (TX) circuit and a receiving (RX) circuit easily. In the example shown in FIG. 5, there is provided only one pair of a transmitting (TX′) circuit 65 and a receiving (RX′) circuit 64. However, it is also possible to generate a predetermined number of test receiving circuits (RX′) 64 or transmitting (TX′) circuits 65 beforehand in accordance with the number of pairs of the transmitting (TX) circuits and receiving (RX) circuits provided for the semiconductor device.

While the preferred embodiments of the present invention have been described, it is to be understood that modifications will be apparent to those skilled in the art without departing the spirit of the invention.

What is claimed is:

1. A semiconductor device that includes two or more transmitting circuits for converting parallel data to serial data and transmitting the converted serial data to external and two or more receiving circuits for receiving serial data from external and converting the received serial data to parallel data,
wherein the semiconductor device further includes a device that connects two or more selected transmitting circuits and two or more selected receiving circuits serially and alternately, and
wherein the semiconductor device enables the serially connected transmitting or receiving circuit in the first stage to input a test signal and to compare the test signal with a signal output from the serially connected receiving or transmitting circuit in the last stage.

2. The semiconductor device according to claim 1,
wherein the semiconductor device further includes a test signal generation circuit that generates the test signal to be inputted to the transmitting or receiving circuit in the first stage.

3. The semiconductor device according to claim 1,
wherein the semiconductor device further includes a test signal comparison circuit that compares the test signal with a signal output from the transmitting or receiving circuit in the first stage.

4. The semiconductor device according to claim 1,
wherein the semiconductor device can use an LSI tester to carry out the comparison between the inputted or output signal and the test signal.

5. The semiconductor device according to claim 1,
wherein the semiconductor device further includes a test receiving or transmitting circuit paired with the transmitting or receiving circuit.

6. A method for testing a semiconductor device having two or more transmitting circuits for converting parallel data to serial data and transmitting the converted serial data to external respectively and two or more receiving circuits for receiving serial data from external and converting the received serial data to parallel data respectively,
wherein two or more selected transmitting circuits and two or more selected receiving circuits are connected serially and alternately,
wherein the serially connected transmitting or receiving circuit in the first stage inputs a test signal, and
wherein the test signal is compared with a signal output from the serially connected receiving or transmitting circuits in the last stage.
